(19) United States
(12) Patent Application Publication
(10) Pub. No.: US 2013/0154282 A1
(43) Pub. Date: Jun. 20, 2013

(54) ELECTRONIC DEVICE HAVING LOCKING MECHANISM

(71) Applicants: WEI-KUANG LIANG, Tu-Cheng (TW); QUAN-GUANG DU, Shenzhen City (CN); CHUN TANG, Shenzhen City (CN)

(72) Inventors: WEI-KUANG LIANG, Tu-Cheng (TW); QUAN-GUANG DU, Shenzhen City (CN); CHUN TANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/586,951

(22) Filed: Aug. 16, 2012

(30) Foreign Application Priority Data
Dec. 16, 2011 (CN) 201110423080.8

(51) Int. Cl. H05K 5/03; E05C 1/10

(52) U.S. Cl. 292/175; 292/145

(57) ABSTRACT

An electronic device includes an enclosure defining an opening and an installation slot, a cover plate attached to the enclosure and adapted to cover the opening of the enclosure, a battery module received in the installation slot, and a locking member slidably mounted to the enclosure. When the locking member is located in a locked position, the locking member secures the cover plate to the enclosure and fixes the battery module in the installation slot. When the locking member is moved to a first unlocked position, the locking member unfixes the battery module from the installation slot. When the locking member is moved to a second unlocked position, the locking member unfastens the cover plate from the enclosure.

### BACKGROUND

1. Technical Field

The present disclosure generally relates to electronic devices, and particularly relates to electronic devices having locking mechanisms.

2. Description of Related Art

Many electronic devices include an enclosure, a cover plate, a battery module, a first locking member, and a second locking member. The enclosure defines an opening. The cover plate is attached to the enclosure and covers the opening of the enclosure. The enclosure further defines a receiving slot for receiving and holding the battery module. The first locking member and the second locking member are mounted to the enclosure and secure the cover plate and the battery module to the enclosure. To disassemble, a user has to first dismantle both the first locking member and the second locking member, and then remove the cover plate and the battery module from the enclosure. It is not convenient for the user. Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device in accordance with an embodiment.

FIG. 2 is an enlarged view of a circled portion II of FIG. 1.

FIG. 3 is an enlarged view of a circled portion III of FIG. 1.

FIG. 4 is similar to FIG. 1, but viewed from a different aspect.

FIG. 5 is a cutaway view of a battery module of FIG. 1.

FIG. 6 is an assembled view of the electronic device of FIG. 1.

FIG. 7 is a cutaway view of the electronic device of FIG. 6.

FIG. 8 is similar to FIG. 6, but viewed from a different aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

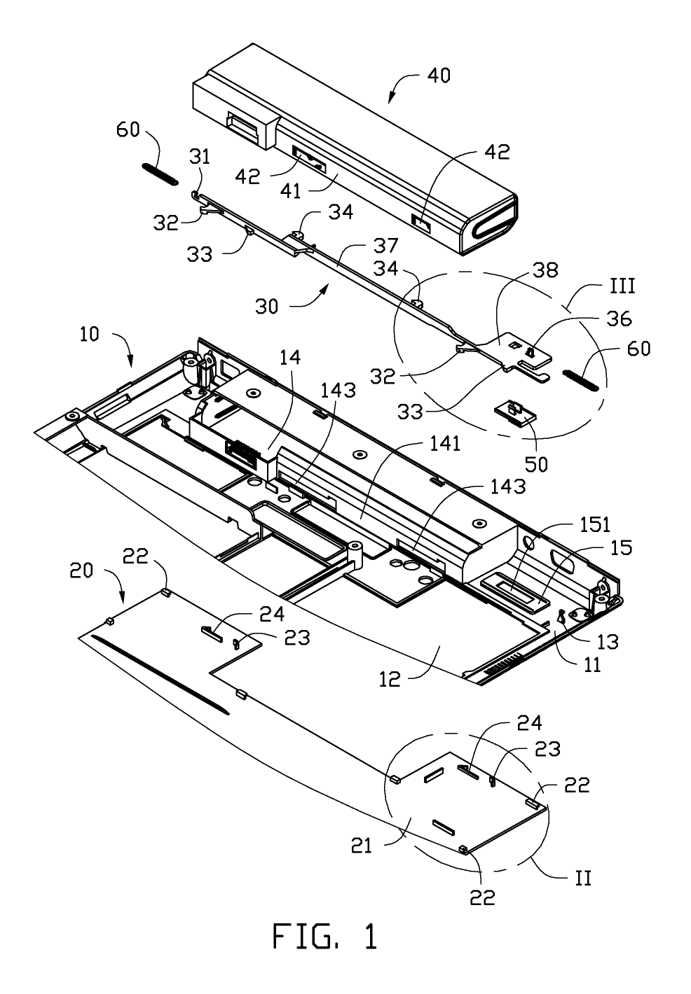

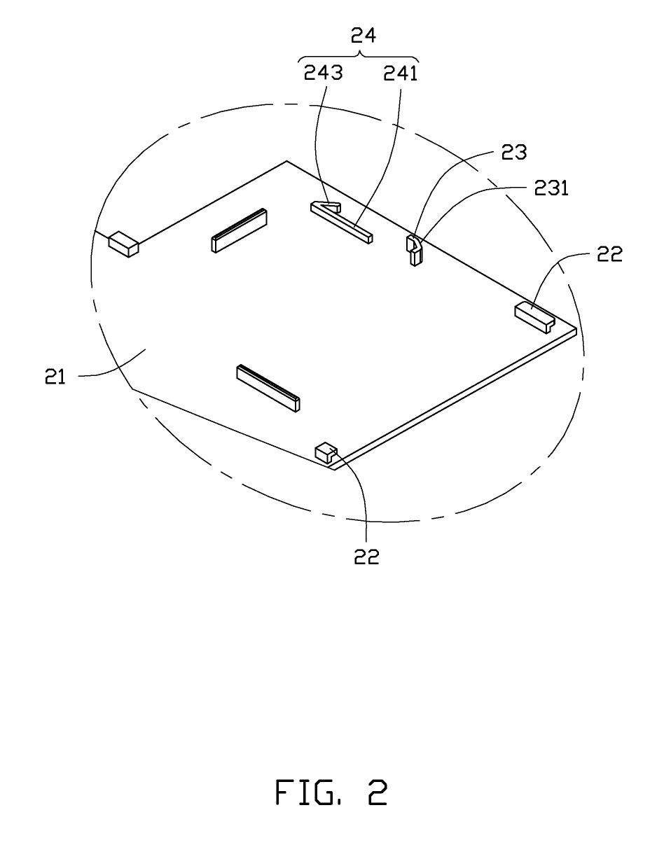

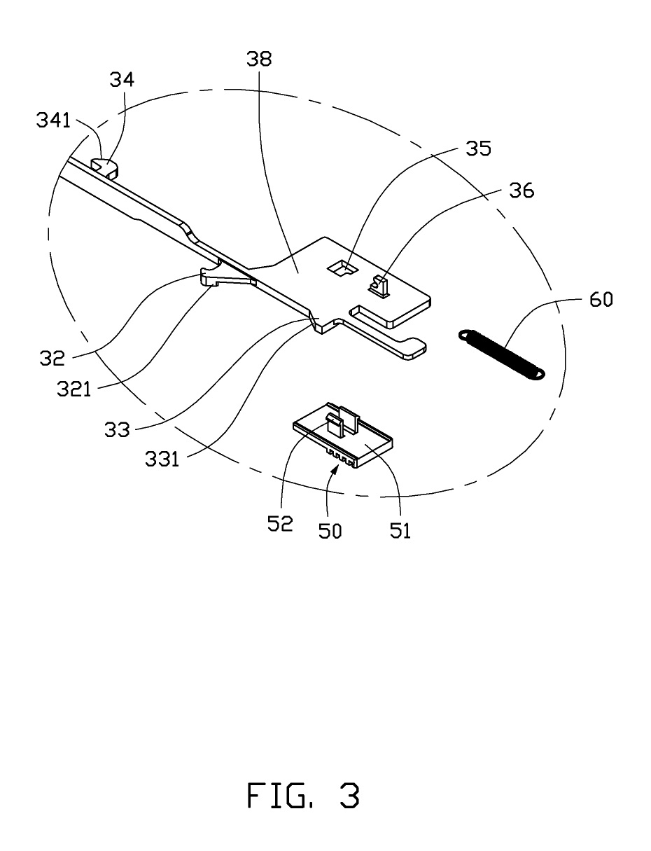

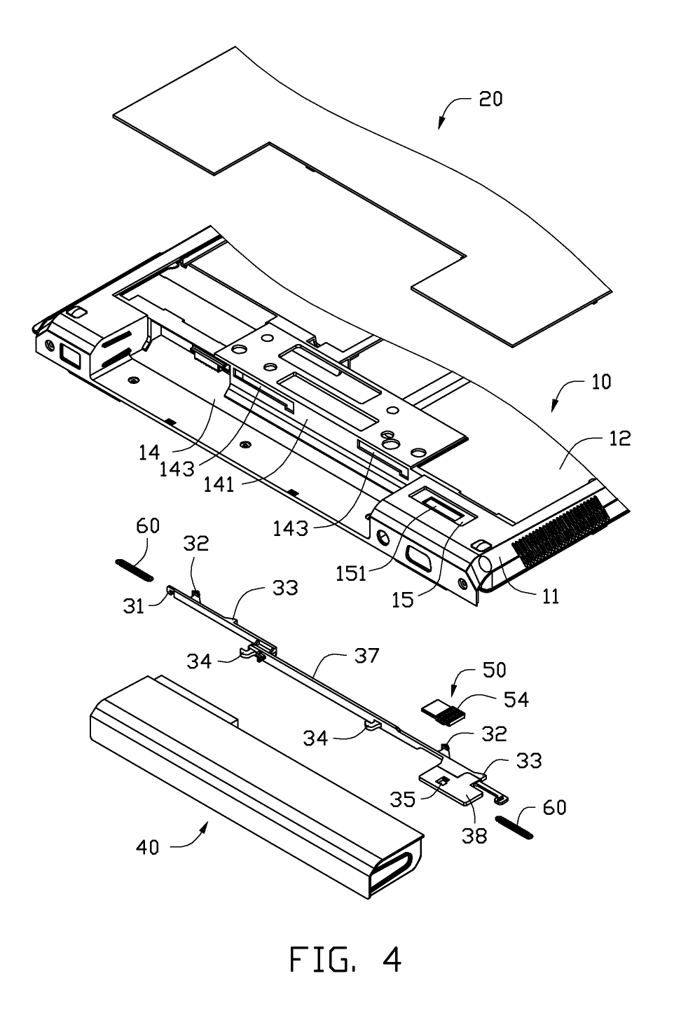

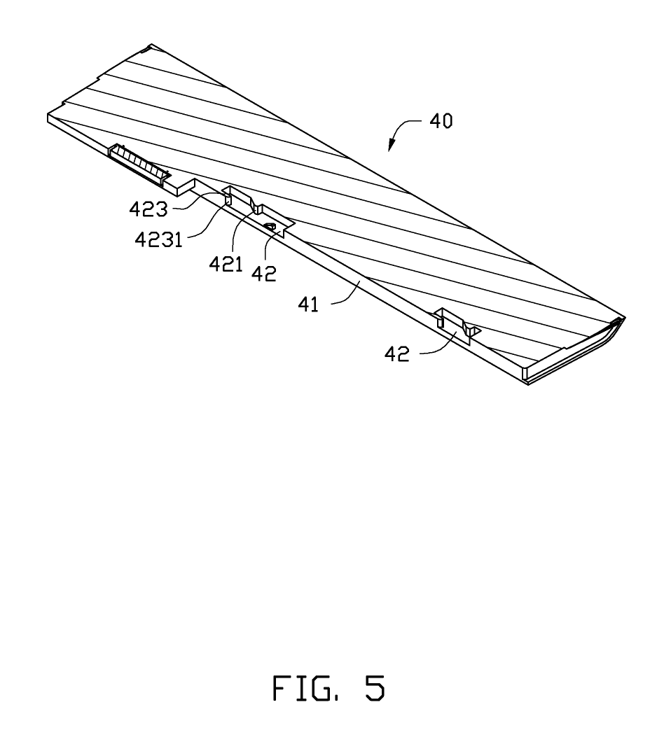

FIGS. 1-5 illustrate an electronic device in accordance with an embodiment. The electronic device includes an enclosure 10, a cover plate 20, a locking member 30, a battery module 40, an operating member 50, and a pair of resilient members 60. The pair of resilient members 60 may a pair of springs, for example. In some embodiments, the electronic device is a notebook computer.

The enclosure 10 includes a main frame body 11. The main frame body 11 has a substantially rectangular shape. The main frame body 11 defines at least one opening 12. A pair of hook pieces 13 protrudes from the main frame body 11 and can engage with the pair of resilient members 60. The enclosure 10 defines an installation slot 14 for receiving and holding the battery module 40. The installation slot 14 includes a blocking wall 141. The blocking wall 141 is substantially perpendicular to a plane of the at least one opening 12. The blocking wall 141 defines a pair of mounting holes 143. The main frame body 11 includes a rectangular installation portion 15 corresponding to the operating member 50. The installation portion 15 is arranged between one of the pair of hook pieces 13 and the installation slot 14. A rectangular opening 151 is defined in the center of the installation portion 15.

The cover plate 20 includes a U-shaped plate body 21. A plurality of L-shaped limiting pieces 22 protrudes from the plate body 21 and is adjacent to the edges of the plate body 21. A pair of resisting pieces 23 and a pair of clasping ribs 24 protrude perpendicularly from the plate body 21. Each of the pair of resisting pieces 23 includes a slant plane 231. Each of the pair of clasping ribs 24 includes a first rib portion 241 and a second rib portion 243 extending obliquely from an end of the first rib portion 241. The angel between the first rib portion 241 and the second rib portion 243 is less than 90 degrees. The length of the first rib portion 241 is greater than the length of the second rib portion 243.

The locking member 30 includes an elongated main body 37 and an installation tab 38. The installation tab 38 extends laterally in a first direction from the main body 37 and is adjacent to an end of the main body 37. A first hook piece 31 is arranged at the other end of the main body 37 and is adapted to engage with one of the pair of resilient members 60. A pair of first clasps 32 and a pair of resisting pieces 33 protrude in a second direction from the main body 37. The second direction is opposite to the first direction. A protrusion 321 extends downwardly from an end of each of the pair of first clasps 32. Each of the pair of resisting pieces 33 includes a slant plane 331. A pair of second clasps 34 extends in the first direction from the main body 37. The installation tab 38 and the pair of second clasps 34 are located in one side of the main body 37; the pair of first clasps 32 and the pair of resisting pieces 33 are located in the other side of the main body 37. The installation tab 38 defines a substantially rectangular installation hole 35. A second hook piece 36 protrudes upwardly from the installation tab 38. The second hook piece 36 is adapted to engage with the other one of the pair of resilient members 60.

The battery module 40 is substantially rectangular in shape. The battery module 40 includes a sidewall 41 corresponding to the blocking wall 141 of the installation slot 14. The sidewall 41 defines a pair of clasping grooves 42. A blocking tab 423 protrudes from a sidewall of each of the pair of clasping grooves 42. A slant plane 4231 is defined at the end of each of the blocking tab 423. A wedge-shaped resisting portion 421 protrudes from a bottom wall of each of the pair of clasping grooves 42. Each of the blocking tab 423 is substantially parallel to the bottom wall of each of the pair of clasping grooves 42.

The operating member 50 includes a rectangular plate body 51, a pair of resilient clipping tabs 52, and a wavy operating portion 54. The pair of clipping tabs 52 protrudes from a side of the plate body 51. The operating portion 54 includes a plurality of raised strips arranged on two opposite sides of the plate body 51. The width of the plate body 51 is substantially equal to the width of the installation portion 15 of the enclosure 10. The length of the plate body 51 is less than the length of the installation portion 15.

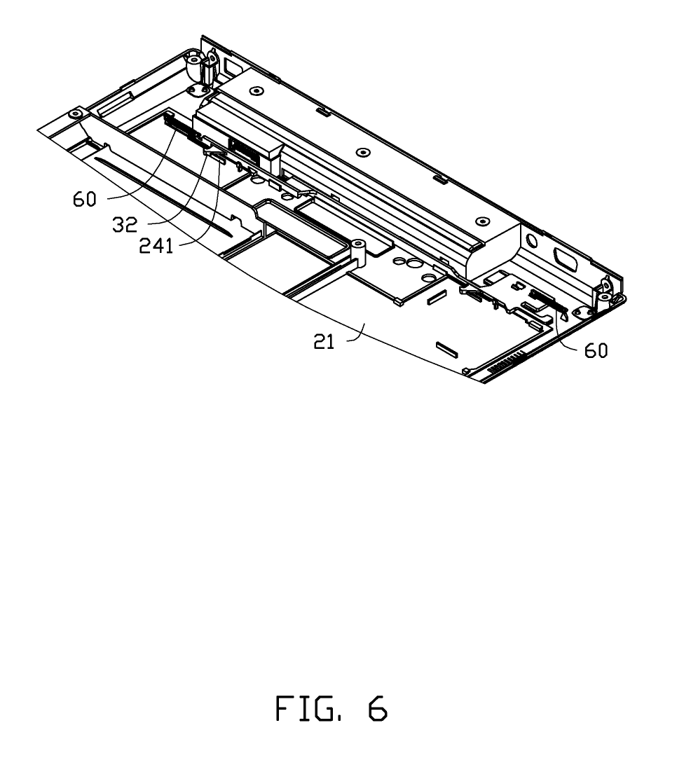

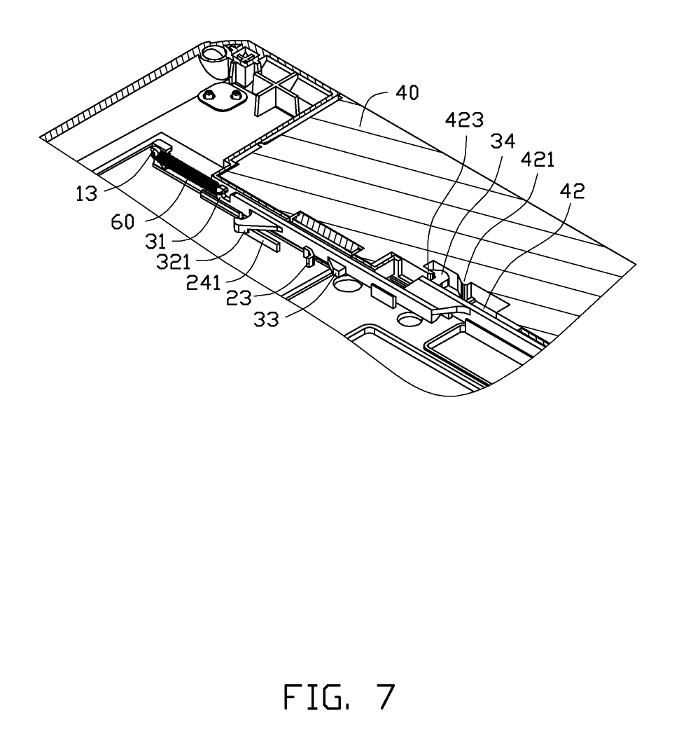

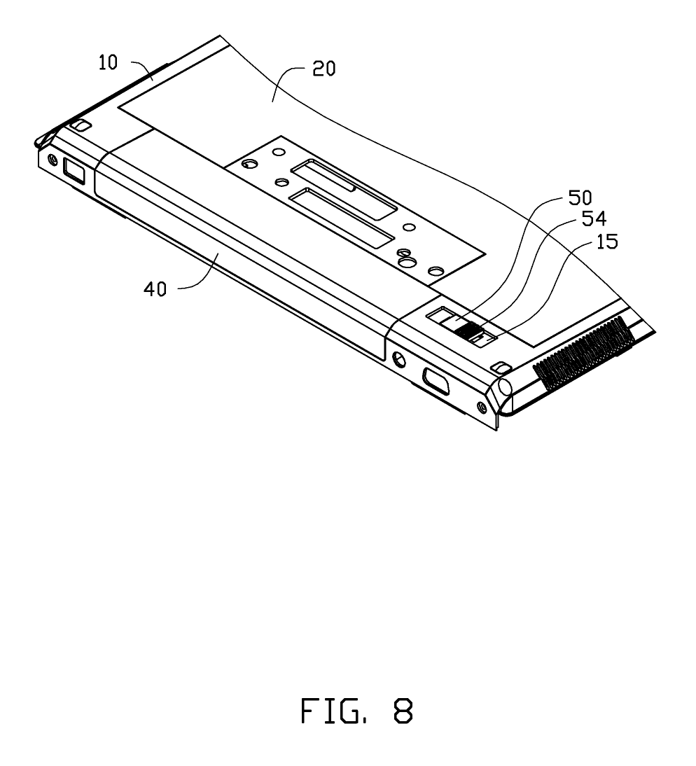

Referring to FIGS. 6-8, in assembly, the pair of second clasps 34 extends through the pair of mounting holes 143 of the enclosure 10. The installation tab 38 of the locking member 30 is placed on the interior side of in the installation portion 15 of the enclosure 10. The installation hole 35 of the installation tab 38 is aligned with the rectangular opening 151 of the enclosure 10. An end of one of the pair of resilient members 60 is connected to the first hook piece 31 and the other end of the one of the pair of resilient members 60 is connected to one of the pair of hook pieces 13 of the enclosure 10. An end of the other one of the pair of resilient members 60 is connected to the second hook piece 36 and the other end of the other one of the pair of resilient members 60 is connected to the other one of the pair of hook pieces 13 of the enclosure. Thus, the locking member 30 is mounted to the enclosure 10.

When mounting the cover plate 20 to the enclosure 10, the cover plate 20 is moved towards the enclosure 10 and the pair of clasping ribs 24 of the cover plate 20 faces the at least one opening 12 of the enclosure 10. When the cover plate 20 is located in an installed position, the second rib portions 243 of the cover plate 20 abut and urge the protrusions 321 of the locking member 30 to move the locking member 30 to the left (assuming the first hook piece 31 of the locking member 30 is at the left and the second hook piece 36 of the locking member is at the right). A left member of the pair of resilient members 60 is compressed and a right member of the pair of resilient members 60 is extended due to the left movement of the locking member 30. When the protrusions 321 go over the second rib portions 243, the pair of resilient members 60 recovers and drives the locking member 30 to move back to the right. The protrusions 321 of the pair of first clasps 32 of the locking member 30 are engaged with the first rib portions 241 of the pair of clasping ribs 24 thereby preventing the cover plate 20 from moving away from the enclosure 10. The plurality of limiting pieces 22 of the cover plate 20 are in contact with the margins of the at least one opening 12. Thus, the cover plate 20 is secured to the enclosure 10 and covers the at least one opening 12 of the enclosure 10.

The pair of resilient clipping tabs 52 of the operating member 50 extends through the rectangular opening 151 of the enclosure 10 and the installation hole 35 of the locking member 30 successively. Thus, the operating member 50 is mounted to the locking member 30 and operable to drive the locking member 30 to move to the left or the right. The plate body 51 of the operating member 50 is slidably mounted to the exterior side surface of the enclosure 10. The wavy operating portion 54 of the operating member 50 facilitates sliding movement of the operating member 50 relative to the enclosure 10.

When installing the battery module 40 to the enclosure 10, the battery module 40 is moved towards and close to the installation slot 14. The slant planes 4231 of two of the blocking tabs 423 of the battery module 40 abut and press a slant plane 341 of each of the pair of second clasps 34 of the locking member 30 to move the locking member 30 to the right until the slant planes 341 of the pair of second clasps 34 go over the slant planes 4231 of two of the blocking tabs 423. The locking member 30 is moved to the left by elastic forces exerted by the pair of resilient members 60 until the pair of second clasps 34 are engaged with two of the blocking tabs 423. Thus, the battery module 40 is fixed in the installation slot 14 of the enclosure 10. During the installation of the battery module 40, the locking member 30 is first moved from an initial position to the right, and then moved from the left back to the initial position by elastic forces exerted by the pair of resilient members 60. The protrusions 321 of the pair of first clasps 32 are moved back and forth along the first rib portions 241 of the cover plate 20, but will not be disengaged from the first rib portions 241 of the cover plate 20. Thus, the cover plate 20 remains secured to the enclosure 10.

When detaching the battery module 40, an acting force is applied to the operating portion 54 of the operating member 50 to actuate the operating member 50 to move the locking member 30 to the right. The pair of second clasps 34 of the locking member 30 is disengaged from two of the blocking tabs 423 and presses two of the resisting portions 421 to drive the battery module 40 to move outwards slightly. Thus, the battery module 40 is unfixed and can be removed from the installation slot 14 of the enclosure 10.

When disassembling the cover plate 20 from the enclosure 10, an acting force is applied to the operating portion 54 of the operating member 50 to actuate the operating member 50 to move the locking member 30 to the left and elastically deform the pair of resilient members 60. When the protrusions 321 of the pair of first clasps 32 of the locking member 30 are disengaged from the first rib portions 241 of the pair of clasping ribs 24 of the cover plate 20, the acting force is released and the pair of resilient members 60 elastically recovers. The locking member 30 is moved to the right by elastic recovery forces exerted by the pair of resilient members 60. The protrusions 321 of the pair of first clasps 32 of the locking member 30 abut and press the second rib portions 243 of the cover plate 20 to drive the cover plate 20 to move outwards. The plurality of L-shaped limiting pieces 22 are disengaged from the enclosure 10. Thus, the cover plate 20 is unfastened and can be removed from the enclosure 10.

In other embodiments, when the battery module 40 is fixed in the installation slot 14 of the enclosure 10 by the pair of second clasps 34 of the locking member 30, the locking member 30 is prevented from moving to the left and unfastening the cover plate 20. When the battery module 40 is unfixed and removable from the enclosure 10, the locking member 30 is allowed to move to the left and unfasten the cover plate. In this way, an ordinary operator is able to avoid performing some improper operations, for example, dismantling the cover plate 20 without first removing the battery module 40.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device comprising:
an enclosure defining an opening and an installation slot;
a cover plate attached to the enclosure and adapted to cover the opening of the enclosure, the cover plate comprises a clasping rib;
a battery module received in the installation slot, the battery module defines a clasping groove; and
a locking member comprising a first clasp and a second clasp;
wherein when the locking member is located in a locked position, the first clasp is engaged with the clasping rib for securing the cover plate to the enclosure and the second clasp is engaged in the clasping groove for fixing the battery module in the installation slot; when the locking member is moved from the lock position to a first unlocked position, the second clasp is disengaged from the clasping groove for releasing the battery module from the installation slot; when the locking member is moved from the locked position to a second unlocked position, the first clasp is disengaged from the clasping rib for releasing the cover plate from the enclosure.

2. The electronic device of claim 1, wherein the locking member is moved in a first direction from the locked position to the first unlocked position, and moved in a second direction from the locked position to the second unlocked position; the first direction is opposite to the second direction.

3. The electronic device of claim 1, further comprising a resilient member, a first end of the resilient member is connected to the enclosure, a second end of the resilient member is connected to the locking member; when a force is applied to the locking member to move the locking member to the first unlocked position or the second unlocked position, the resilient member is deformed; when the force is released, the resilient member recovers and drives the locking member back to the locked position.

4. The electronic device of claim 1, wherein the locking member comprises an elongated main body, the first clasp and the second clasp protrude from two opposite sides of the main body.

5. The electronic device of claim 4, wherein a protrusion extends from the first clasp;
when the locking member is located in the locked position, the protrusion is engaged with the clasping rib of the cover plate.

6. The electronic device of claim 5, wherein the clasping rib comprises a first rib portion and a second rib portion extending obliquely from an end of the first rib portion; when the locking member is located in the locked position, the protrusion is engaged with first rib portion.

7. The electronic device of claim 6, wherein the second rib portion of the clasping rib is adapted to abut and press the first clasp of the locking member thereby driving the locking member to move in the second direction when the cover plate is located in an installed position.

8. The electronic device of claim 1, wherein the battery module comprises a blocking tab extending laterally from a sidewall of the clasping groove; when the locking member is located in the locked position, the second clasp is engaged with the blocking tab; when the locking member is located in the first unlocked position, the second clasp is disengaged from the blocking tab.

9. The electronic device of claim 8, wherein the battery module comprises a wedge-shaped resisting portion protruding from a bottom wall of the clasping groove; when the locking member is moved in the first direction to the first unlocked position, the second clasp is adapted to abut and press the resisting portion thereby driving the battery module to move outwards.

10. The electronic device of claim 4, wherein the locking member further comprises an installation tab extending laterally from the main body, the installation tab defines an installation hole; the electronic device further comprises an operating member, the operating member comprises a rectangular plate body and a pair of clipping tabs protruding from the rectangular plate body.

11. The electronic device of claim 10, wherein the enclosure further comprises a rectangular installation portion configured to accommodate the operating member, the installation portion defines a rectangular opening, the pair of clipping tabs are snapped into the rectangular opening of the enclosure and the installation hole of the locking member successively thereby securing the operating member to the locking member.

12. The electronic device of claim 11, wherein the operating member further comprises a plurality of raised strips arranged on two opposite sides of the plate body.

13. The electronic device of claim 11, wherein a width of the plate body is substantially equal to a width of the installation portion of the enclosure.

14. The electronic device of claim 11, wherein a length of the plate body is less than a length of the installation portion thereby enabling slidable movement of the operating member relative to the installation portion.

15. The electronic device of claim 6, wherein an angel between the first rib portion and the second rib portion is less than 90 degrees.

16. The electronic device of claim 6, wherein a length of the first rib portion is greater than a length of the second rib portion.

17. An electronic device comprising:
an enclosure defining an opening and an installation slot;
a cover plate attached to the enclosure and adapted to cover the opening of the enclosure;
a battery module received in the installation slot; and
a locking member slidably mounted to the enclosure; when the locking member is located in a locked position, the locking member secures the cover plate to the enclosure and fixes the battery module in the installation slot; when the locking member is moved from the lock position to a first unlocked position, the locking member releases the battery module from the installation slot; when the locking member is moved from the locked position to a second unlocked position, the locking member unfastens the cover plate from the enclosure.

18. The electronic device of claim 17, wherein the locking member is moved in a first direction from the locked position to the first unlocked position, and moved in a second direction from the locked position to the second unlocked position; the first direction is opposite to the second direction.

19. The electronic device of claim 17, further comprising a resilient member, a first end of the resilient member is connected to the enclosure, a second end of the resilient member is connected to the locking member; when a force is applied to the locking member to move the locking member to the first unlocked position or the second unlocked position, the resilient member is deformed; when the force is released, the resilient member recovers and drives the locking member back to the locked position.
